(19) United States
(12) Patent Application Publication
(10) Pub. No.: US 2015/0289425 A1
(43) Pub. Date: Oct. 8, 2015

(54) MOLDED FIBER-REINFORCED COMPOSITE MATERIAL PRODUCT AND METHOD OF PRODUCING THE SAME

(71) Applicant: Mitsubishi Rayon Co., Ltd., Chiyoda-ku, Tokyo (JP)

(72) Inventors: Keigo Yoshida, Toyohashi-shi (JP); Yoshiaki Saitou, Tokyo (JP); Hisao Koba, Toyohashi-shi (JP); Tomonori Terasawa, Toyohashi-shi (JP)

(73) Assignee: Mitsubishi Rayon Co., Ltd., Chiyoda-ku, Tokyo (JP)

(21) Appl. No.: 14/437,342

(22) PCT Filed: Oct. 22, 2013
(86) PCT No.: PCT/JP2013/078536

§ 371 Date: Apr. 21, 2015

(30) Foreign Application Priority Data
Oct. 23, 2012 (JP) 2012-233554

(51) Int. Cl. H05K 9/00; B29C 65/70; B29C 65/78

(52) U.S. Cl. CPC H05K 9/0088; B29C 65/7802; B29C 65/70; H05K 9/009; B29K 2063/00

(57) ABSTRACT

A molded fiber-reinforced composite material product having a thin sheet shape, includes: an electromagnetic wave blocking prepreg made of conductive fibers and a thermosetting matrix resin; an electromagnetic wave transparent prepreg made of non-conductive fibers and a thermosetting matrix resin; a first layer formed by joining the electromagnetic wave blocking prepreg and the electromagnetic wave transparent prepreg together at a joining line perpendicular to the thickness direction of the molded fiber-reinforced composite material product; a second layer formed on the first layer and including the electromagnetic wave transparent prepreg disposed to cover at least a portion of the joining line; and an electromagnetic wave transparent section not including the electromagnetic wave blocking prepreg in the thickness direction.

### TECHNICAL FIELD

The present invention relates to a molded fiber-reinforced composite material product having excellent lightweight properties, thin thickness properties, and rigidity. More specifically, the present invention relates to a molded fiber-reinforced composite material product in which a section of a thin sheet formed of a thermosetting resin and reinforcement fibers continuously arranged in a direction perpendicular to the thickness direction has high electromagnetic wave transparency in the thickness direction and a method of producing the same.

This application is based upon and claims the benefit of priority of the prior Japanese Patent application No. 2012-233554, filed on Oct. 23, 2012, the entire contents of which are incorporated herein by reference.

### BACKGROUND ART

Fiber-reinforced composite material (hereinafter, referred to as “FRP”) is lightweight, highly strong, and highly rigid, and thus is widely used for sport and leisure applications to industrial applications such as automobiles and aircraft.

FRP is also used in a casing or the like for electrical and electronic equipment such as a personal computer (hereinafter, referred to as a “PC”), electrical household appliances, and medical instruments. The electrical and electronic equipment such as a PC or a telephone is composed of small, lightweight, and thin parts for mobilization thereof. In particular, with respect to the casing of these devices, in order to prevent break of the internal parts and fracture of the casing itself even when the load is applied to the casing from the outside and the casing is partially bent and thus comes in contact with internal parts, the casing needs to have mechanical properties such as high strength and high rigidity.

In addition, a notebook PC, for example, commonly has a radio communication function such as a wireless LAN and the casing needs to have a structure though which electromagnetic wave is not blocked in the vicinity of the antenna portion incorporated in the PC body.

Patent Document 1 proposes a structure of a display module 103 in which an antenna 102 is disposed around the upper casing 101 of the display part as illustrated in FIG. 1 and an outer decorative cover 100 is formed of an electromagnetic wave transparent material. In this case, since function of the structure having strength and function of the exterior are separated from each other and thus a combination of members for each function is required, it leads to increase in the thickness of the display part. Recently, demand for reducing weight and thickness becomes especially higher for mobile PCs and thus it is necessary to further reduce the weight and thickness.

Patent Document 2 discloses a structure of an upper casing formed of a carbon fiber reinforced plastic (CFRP). In the casing structure, a glass fiber reinforced plastic (GFRP) as a non-conductive material is partially used around the upper casing to ensure electromagnetic wave transparency and simplify the structure compared to that in Patent Document 1, thereby reducing the weight and thickness.

### CITATION LIST

### Patent Document

Patent Document 1: JP 2008-234100 A

Patent Document 2: JP 2009-169506 A

### DISCLOSURE OF THE INVENTION

### Problem to be Solved by the Invention

In view of problems in the prior art, an object of the present invention is to provide a molded fiber-reinforced composite material product having excellent rigidity, lightweight properties, and thin thickness properties and further having a section which is transparent for electromagnetic wave.

### Means for Solving Problem

A molded fiber-reinforced composite material product having a thin sheet shape according to the first aspect of the present invention includes: an electromagnetic wave blocking prepreg made of conductive fibers and a thermosetting matrix resin; an electromagnetic wave transparent prepreg made of non-conductive fibers and a thermosetting matrix resin; a first layer formed by joining the electromagnetic wave blocking prepreg and the electromagnetic wave transparent prepreg together at a joining line perpendicular to the thickness direction of the molded fiber-reinforced composite material product; a second layer formed on the first layer and including the electromagnetic wave transparent prepreg disposed to cover at least a portion of the joining line; and an electromagnetic wave transparent section not including the electromagnetic wave blocking prepreg in the thickness direction.

The second layer may be formed by joining the electromagnetic wave blocking prepreg and the electromagnetic wave transparent prepreg together through a second joining line perpendicular to the thickness direction, and in the state where the first layer and the second layer are laminated, both end portions of the first joining line and both end portions of the second joining line may be disposed so as not overlap with each other on same lines.

The molded fiber-reinforced composite material product further includes a third layer which is formed on the opposite side of the second layer to the first layer and formed by joining the electromagnetic wave blocking prepreg and the electromagnetic wave transparent prepreg together at a joining line, and the second layer may be formed only from the electromagnetic wave transparent prepreg.

The electromagnetic wave blocking prepreg and the electromagnetic wave transparent prepreg may be unidirectional prepreg.

The electromagnetic wave blocking prepreg and the electromagnetic wave transparent prepreg constituting the first layer may be disposed such that fiber orientation directions thereof are perpendicular to each other.

The second layer may be constituted of unidirectional prepreg and the unidirectional prepreg of the first layer and the unidirectional prepreg of the second layer being adjacent to each other may be laminated such that fiber orientation directions thereof are perpendicular to each other.

The electromagnetic wave blocking prepreg may be unidirectional prepreg and the electromagnetic wave transparent prepreg may be fabric prepreg.

In addition, the conductive fiber may preferably be a carbon fiber and the non-conductive fiber may further preferably be a glass fiber.

In the molded fiber-reinforced composite material product according to the first aspect of the invention, the thickness of the molded fiber-reinforced composite material product may preferably be 1.2 mm or less and the thickness thereof may further preferably be 0.6 mm or less.

A method of producing a molded fiber-reinforced composite material product according to the second aspect of the present invention includes: preparing an electromagnetic wave blocking prepreg made of conductive fibers and a thermosetting matrix resin and an electromagnetic wave transparent prepreg made of non-conductive fibers and a thermosetting matrix resin; forming a first layer by joining the electromagnetic wave blocking prepreg and the electromagnetic wave transparent prepreg together in directions perpendicular to the thickness direction; forming a second layer, which include the electromagnetic wave transparent prepreg that covers at least a portion of the joining line between the electromagnetic wave blocking prepreg and the electromagnetic wave transparent prepreg of the first layer, on the first layer, and thus forming a laminated body including at least the first layer and the second layer; and curing the laminated body.

### Effect of the Invention

The molded fiber-reinforced composite material product according to the present invention can reduce thickness and weight while maintaining sufficient rigidity. Further, a portion of the molded fiber-reinforced composite material product according to the present invention can transmit the electromagnetic wave so that the antenna inside the structure receives the electromagnetic wave of the wireless LAN or the like. In addition, the aspect of the present invention can provide the method of producing the molded composite material product.

### BRIEF DESCRIPTION OF DRAWINGS

FIG. 1 is a diagram illustrating a configuration of a casing for a notebook PC;

FIG. 2 is a perspective view of a molded fiber-reinforced composite material product according to an embodiment of the present invention;

FIG. 3 illustrates an example of a cross-sectional view of the molded fiber-reinforced composite material product according to the embodiment of the present invention;

FIG. 4 illustrates an example of a cross-sectional view of the molded fiber-reinforced composite material product according to the embodiment of the present invention;

FIG. 5 illustrates an example of a cross-sectional view of the molded fiber-reinforced composite material product according to the embodiment of the present invention;

FIG. 6 illustrates an example of a cross-sectional view of the molded fiber-reinforced composite material product according to the embodiment of the present invention;

FIG. 7 illustrates an example of a cross-sectional view of the molded fiber-reinforced composite material product according to the embodiment of the present invention;

FIG. 8 illustrates an example of a cross-sectional view of the molded fiber-reinforced composite material product according to the embodiment of the present invention;

FIG. 9 illustrates an example of a cross-sectional view of the molded fiber-reinforced composite material product according to the embodiment of the present invention;

FIG. 10 illustrates an example of a cross-sectional view of the molded fiber-reinforced composite material product according to the embodiment of the present invention; and

FIG. 11 illustrates an example of a prepreg-joined sheet according to the embodiment of the present invention.

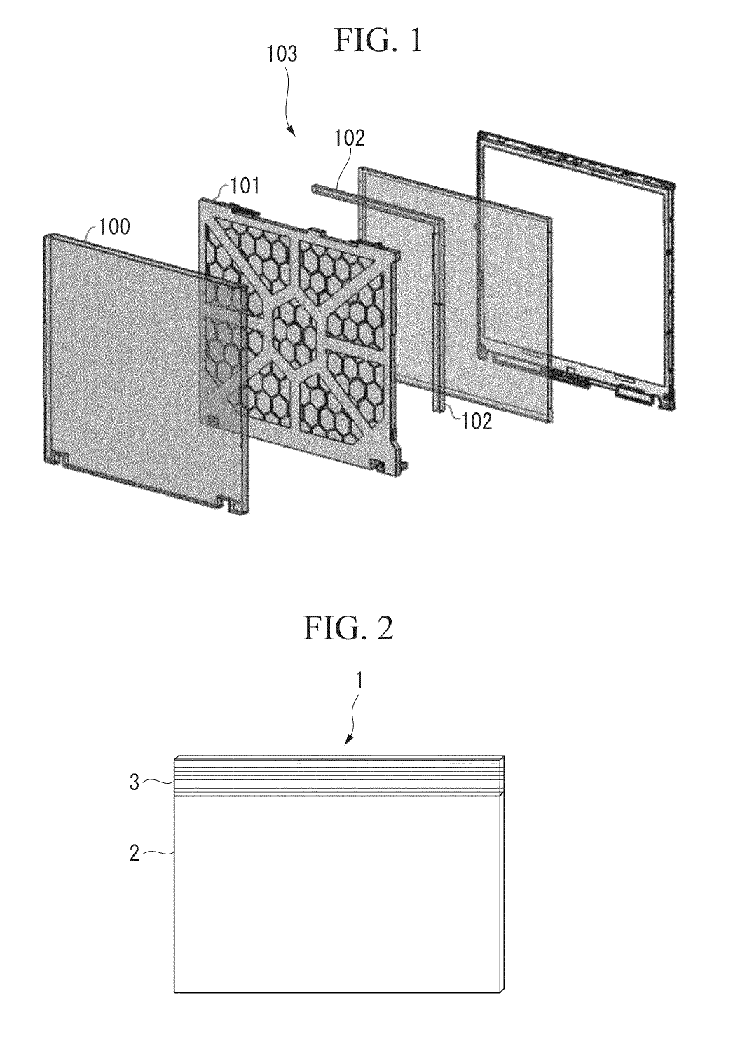

### MODE(S) FOR CARRYING OUT THE INVENTION

Molded fiber-reinforced composite material products according to embodiments of the present invention will be described below in detail with reference to the drawings. In addition, the present invention is not limited to contents illustrated in the drawings.

FIG. 2 is a diagram illustrating an example of the molded fiber-reinforced composite material product (molded composite material product) according to the embodiment of the present invention. The molded composite material product 1 has a thin sheet shape and is composed of a portion 2 (electromagnetic wave blocking portion 2) including at least conductive fibers and a thermosetting resin and a portion 3 (electromagnetic wave transparent portion 3) including non-conductive fibers and the thermosetting resin with no conductive fibers.

### Thermosetting Resin

Examples of the thermosetting resins capable of being used for the molded composite material product according to the embodiments of the present invention may include an epoxy resin, a vinyl ester resin, an unsaturated polyester resin, a polyimide resin, a maleimide resin, a phenolic resin, and the like. When a carbon fiber is used as a reinforcing fiber, the epoxy resin or the vinyl ester resin is preferably used in terms of adhesive property to the carbon fiber.

Moreover, since PC and home electric appliances requires flame retarding performance in many cases, a thermosetting resin added with a flame retarding material is preferably used. Examples of general flame retarding materials may include a bromine-based compound, a phosphorus-based compound, a phosphorus and nitrogen-based compound, a metal hydroxide, a silicon-based compound, a hindered amine compound, and the like, and the flame retarding performance can be obtained by adding these flame retarding materials to the above resins. The flame retarding performance can be evaluated using UL94 standard flame test or the like as a method of evaluating flame retardancy.

### Fibers Constituting Electromagnetic Wave Blocking Portion

The electromagnetic wave blocking portion is a portion having strength and rigidity necessary to protect the internal display device or the like from external pressing force. Fibers (conductive fibers) reinforcing the electromagnetic wave blocking portion are not particularly limited as long as the material has necessary strength and rigidity. Carbon fibers are preferably used in terms of weight lightening and rigidity. In addition, examples of the fibers reinforcing the electromagnetic wave blocking portion may include long fibers and short fibers in form, and the long fibers are preferably used in terms of rigidity among the above fibers.

Examples of the form of the long fibers may include an UD sheet (unidirectional sheet) in which a large number of long fibers are aligned side by side in one direction to be a sheet shape and a fabric or the like made of the long fibers. In particular, a form obtained by alternately laminating an UD sheet in which the long fibers are oriented to 0° and an UD sheet in which the long fibers are oriented to 90° or a form obtained by laminating the fabrics made of the long fibers is preferred in terms of excellent rigidity.

In this embodiment, the electromagnetic wave blocking portion is a portion containing one or more of electromagnetic wave blocking prepreg to be described below in the thickness direction, and it also includes a portion in which the electromagnetic wave blocking prepreg and electromagnetic wave transparent prepreg to be described below are laminated.

### Fibers Constituting Electromagnetic Wave Transparent Portion

Since an antenna device for such as a wireless LAN is arranged immediately below the electromagnetic wave transparent portion, the electromagnetic wave transparent portion is necessary to have electromagnetic wave transparency. When carbon fibers or metal fibers, which are conductive materials, are used as fibers constituting an electromagnetic wave transparent complex, it cannot have sufficient electromagnetic wave transparency. Accordingly, non-conductive materials such as a glass fiber need to be used for the electromagnetic wave transparent complex. The glass fiber is preferably used as the non-conductive fiber in terms of non-conductive property and weight lightening and rigidity. In addition, examples of the form of the reinforcing fibers may include long fibers and short fibers, and the long fibers are preferably used in terms of rigidity among the above fibers.

In this embodiment, the electromagnetic wave transparent portion is a portion not including electromagnetic wave blocking prepreg to be described below in the thickness direction.

### Molded Fiber-Reinforced Composite Material Product

A molded fiber-reinforced composite material product according to the embodiment of the present invention can be obtained in such a manner that carbon fiber prepreg (electromagnetic wave blocking prepreg) obtained by impregnating a carbon fiber UD sheet with a thermosetting resin in advance and glass fiber prepreg (electromagnetic wave transparent prepreg) obtained by impregnating a glass fiber UD sheet with a thermosetting resin in advance are laminated in combination therewith so as to obtain desired form and characteristics and then are cured by autoclave molding, vacuum bag molding, press molding, or the like.

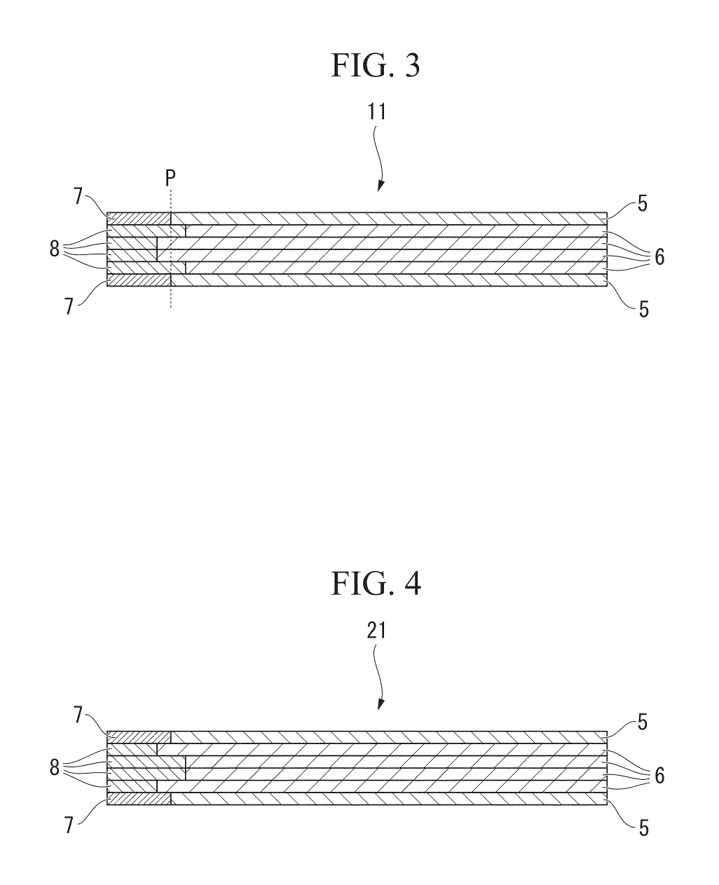

FIGS. 3 to 10 illustrate cross-sections of the molded fiber-reinforced composite material product constituted of carbon fiber prepreg and glass fiber prepreg according to this embodiment, respectively.

Molded fiber-reinforced composite material products 11, 21, 31, 41, 51, 61, 71, and 81 illustrated in FIGS. 3 to 10 have common configurations as follows: a first layer formed by joining the carbon fiber prepreg (electromagnetic wave blocking prepreg) and the glass fiber prepreg (electromagnetic wave transparent prepreg) together through a first joining line perpendicular to the thickness direction of the molded fiber-reinforced composite material product and a second layer formed on the first layer and having the electromagnetic wave transparent prepreg which is disposed to cover at least a portion of the first joining line is provided; and an electromagnetic wave transparent portion not including the electromagnetic wave blocking prepreg in the thickness direction is provided. It is further preferred that the electromagnetic wave transparent prepreg of the second layer is disposed to cover the entire of the first joining line.

In order to understand these configurations, the cross-sections illustrated in FIGS. 3 to 10 are to illustrate by selecting cross-sections which traverse the joining line and are parallel to the thickness direction. In the shape illustrated in FIG. 2, the cross-section of the molded fiber-reinforced composite material product in the short-side direction is a typical selection.

In order to obtain strength and rigidity required for the molded composite material product, moreover, the carbon fiber prepreg and the glass fiber prepreg are preferably laminated taking the orientation of the fibers into consideration, respectively.

The invention is not limited to the configurations illustrated in FIG. 2 and FIGS. 3 to 10. For example, in FIG. 2 and FIGS. 3 to 10, the electromagnetic wave transparent portion is disposed at an end in a long-side direction of the molded composite material product. However, since an antenna for such as a wireless LAN is often arranged around a display device of a notebook PC, the electromagnetic wave transparent portion may be disposed in a short-side direction as well as the long-side direction. In addition, the electromagnetic wave transparent portion may be disposed, for example, at the center of the molded fiber-reinforced composite material product depending on the arrangement of the antenna, and any form will be good so long as a portion of the molded fiber-reinforced composite material product is constituted only of the glass fiber prepreg in the thickness direction.

For easy explanation in the following description, the shape illustrated in FIG. 2 is used as an example, and the cross-sections illustrated in FIGS. 3 to 10 are cross-sections in the short-side direction of the molded fiber-reinforced composite material product in the shape illustrated in FIG. 2, the short-side direction of the molded composite material product is defined as 0° (direction of 0°), and the long-side direction of the molded composite material product is defined as 90° (direction of 90°).

Reference numeral 5 represents carbon fiber prepreg as a unidirectional material in which the fiber direction is 90°, and reference numeral 6 represents carbon fiber prepreg as a unidirectional material in which the fiber direction is 0°. Similarly, reference numeral 7 represents glass fiber prepreg as a unidirectional material in which the fiber direction is 90°, and reference numeral 8 represents glass fiber prepreg as a unidirectional material in which the fiber direction is 0°. In addition, reference numeral 17 represents glass fiber prepreg as a fabric material in which a warp direction is 90°, and reference numeral 18 represents glass fiber prepreg as a fabric material in which a warp direction is 0°. Furthermore, in the present invention, the carbon fiber prepreg and the glass fiber prepreg in which the fiber directions are aligned in one direction are collectively referred to as unidirectional prepreg, and the carbon fiber prepreg and the glass fiber prepreg having the fiber in the form of fabric are collectively referred to as fabric prepreg.

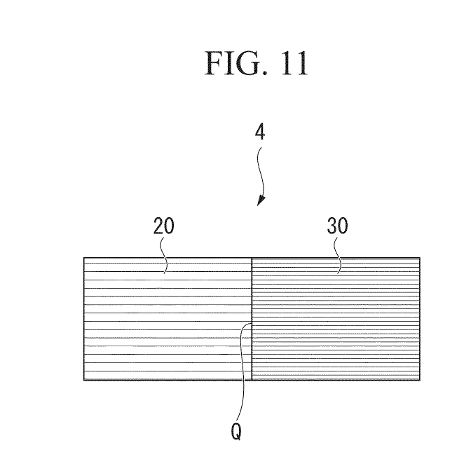

As illustrated in FIG. 11, carbon fiber prepreg 20 and glass fiber prepreg 30 are joined to each other at a joining line Q perpendicular to the thickness direction, thereby forming a prepreg-joined sheet 4. After molding, the joining line Q becomes a joining line between the carbon fiber prepreg 2 and the glass fiber prepreg 3.

When the all joining lines Q in each of the prepreg-joined sheets to be laminated to mold the molded composite material product are disposed on a same line, the strength of the molded composite material product becomes low. Therefore, it is preferred to laminate by shifting joining positions as illustrated in FIGS. 3 and 4 (so that the joining line Q does not overlap on the same line). In this case, it is preferred that at least both end portions of the joining lines are disposed so as not to overlap with each other on a same line in a state in which adjacent two layers are laminated in the thickness direction, and it is further preferred that any of the joining lines are disposed so as not to overlap with each other on a same line. In addition, even when two layers have a portion in which the joining lines overlap with each other on a same line, it is preferred that the joining line of other layers is configured so as not to exist on the portion on which the joining lines overlap on the same line.

In addition, FIGS. 3 and 4 illustrate the embodiment according to the present invention, but the present invention is not limited to the illustrated configurations. In addition, the joining line Q is not particularly limited in shape, but has preferably a simple shape such as a straight line in terms of easiness of production or the like.

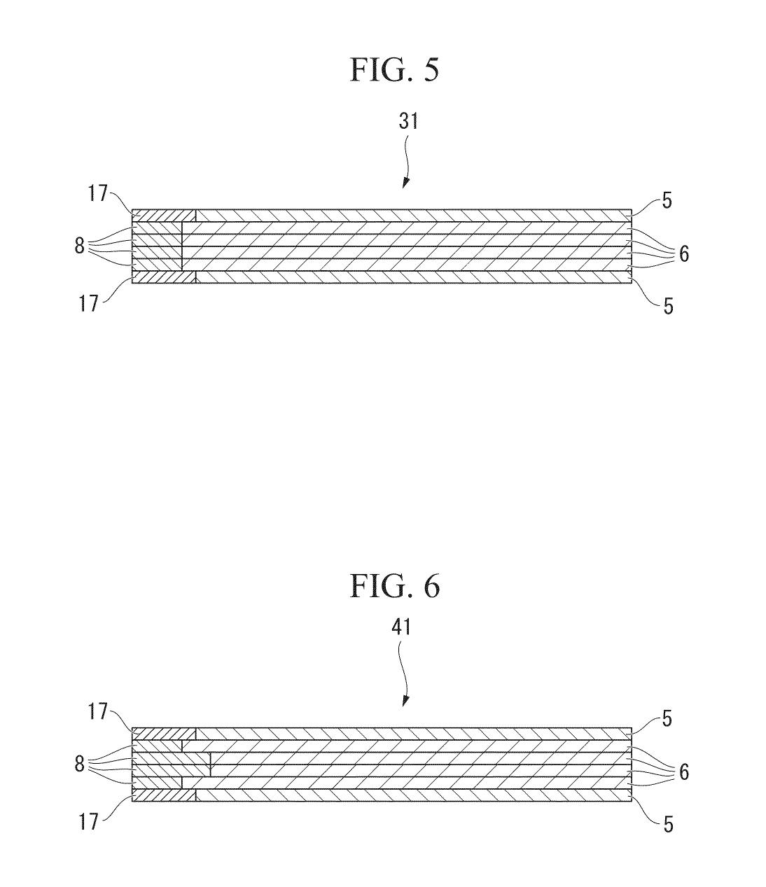

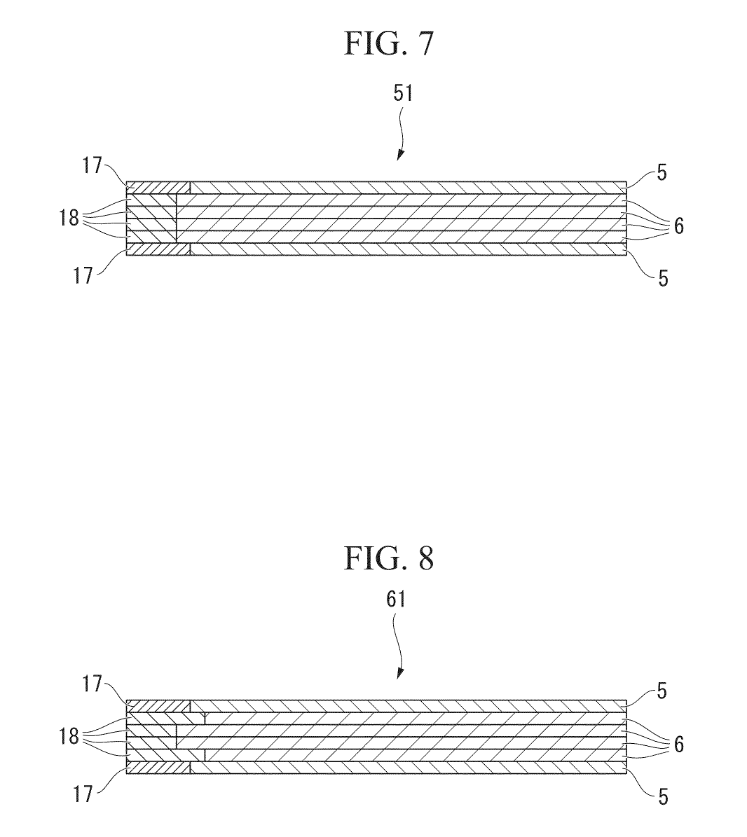

As illustrated in FIGS. 5 and 7, in the case where joining positions (arrangement of the joining lines) of inner layers other than outermost layers (uppermost layer and lowermost layer) are the same, if the fiber direction of the outermost layers disposed on the joining position of the inner layers is 90°, the strength is reduced at the joining position of the inner layers as described above. In such a case, it is possible to prevent the reduction of the strength by disposing glass fiber prepreg 17 of a fabric material at the outermost layers.

As illustrated in FIGS. 3 and 4 or FIG. 6, when the joining positions of the inner layers other than the outermost layers (uppermost layer and lowermost layer) are laminated by shifting from each other, the glass fiber prepreg 7 of 90° as illustrated in FIGS. 3 and 4 and glass fiber prepreg 18 of the fabric material as illustrated in FIG. 6 can be used for the glass fiber prepreg of the outermost layers.

As illustrated in FIGS. 7 and 8, two kinds of glass fiber prepreg 17 and 18 of fabric materials can be also used for the outermost layers and the inner layers, respectively.

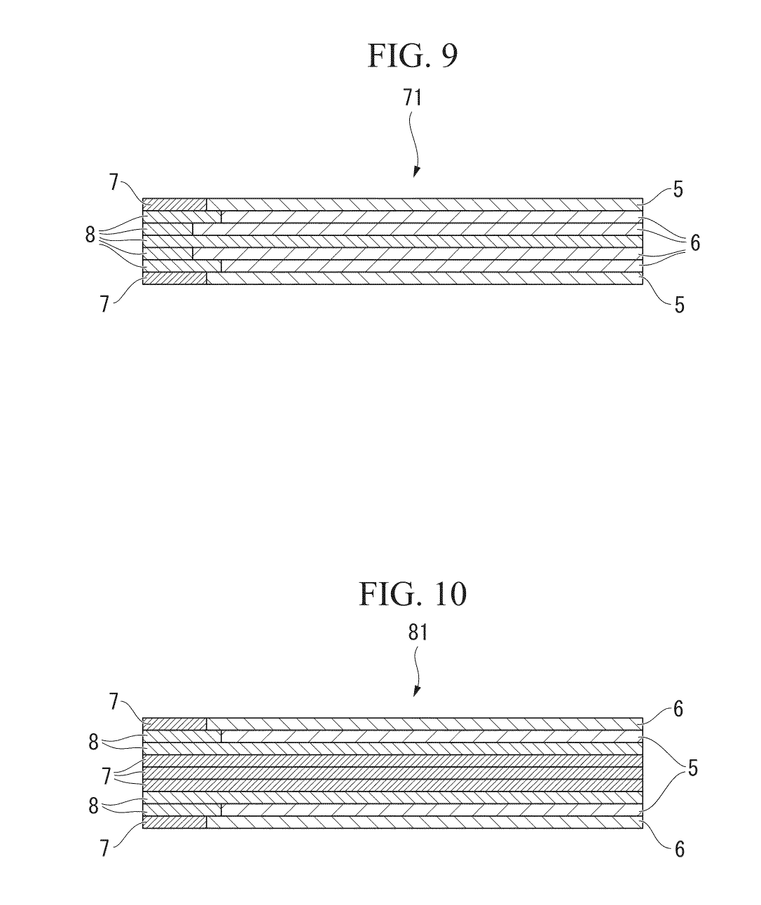

As illustrated in a middle layer of FIG. 9, the glass fiber prepreg 8 may be present to lie over the entire surface of the molded fiber-reinforced composite material product as continuous prepreg not having a joining portion. In addition, from the viewpoint of the electromagnetic wave transparency, the continuous prepreg not having the joining portion is not limited to the glass fiber prepreg as long as being electromagnetic wave transparent prepreg such as of a non-conductive fiber.

As illustrated in FIG. 10, the form in which one prepreg and the other prepreg are perpendicularly joined to each other in an extending direction so as to have the fiber direction of 90° and the fiber direction of 0°, respectively, is preferred to make the appearance of the fiber-reinforced composite material according to the present invention favorable. In the case where both kinds of the prepreg joined to each other in the extending direction have the fiber direction of 0°, respectively, a minute dent derived from a curing shrinkage of a matrix resin during the molding easily occurs on the surface of the molded fiber-reinforced composite material product when a minute gap occurs between both kinds of the prepreg at the joining portion, and on the other hand, in the case where both sides of the prepreg joined to each other in the extending direction have the fiber direction of 90°, respectively, minute turbulence derived from a migration of a matrix resin and a reinforcement fiber during the molding easily occur on the surface of the molded fiber-reinforced composite material product.

In order to suppress the propagation of cracks when the cracks are generated at the joining portion on the outermost layer, furthermore, the fibers of prepreg coming in contact with the joining line between the electromagnetic wave blocking prepreg and the electromagnetic wave transparent prepreg of the outermost layer in the thickness direction are preferably oriented in a direction of 0°, 5 and the joining line between electromagnetic wave blocking prepreg and electromagnetic wave transparent prepreg of the inner layer coming in contact with the outermost layer is preferably disposed so as not to overlap with the joining line on the outermost layer on the same line.

The width of the glass fiber portion (electromagnetic wave transparent portion) should conform to the size of an incorporated antenna and thus is about 10 to 50 mm. The overlapping width of the glass fiber portion and the carbon fiber portion is preferably about 5 to 20 mm.

The thickness of the molded fiber-reinforced composite material product is preferably 1.2 mm or less and more preferably 0.6 mm or less.

An example of a method of producing the molded composite material product (FIG. 2) according to the embodiment of the present invention will be described below

<Lamination of Fiber-Reinforced UD Prepreg>

First, carbon fiber prepreg obtained by impregnating a thermosetting resin composition into carbon fibers and glass fiber prepreg obtained by impregnating a thermosetting resin composition into glass fibers are cut into desired dimensions. The lamination is performed in order from a lower layer to obtain a predetermined lamination structure.

<Press Molding>

Upper and lower molds having a smooth shape can be used in a press molding method. In addition, molds having a partially convex or concave shape can be used to obtain desired structure and design. The upper mold is not used in a vacuum bag molding method. A prepreg laminated body is subjected to heating and molding while being pressurized by the upper and lower molds in a state where a metal mold is closed. After the molding, the cured prepreg laminated body is removed from the mold, thereby obtaining a thin sheet in which a carbon fiber portion (electromagnetic wave blocking portion) and a glass fiber portion (electromagnetic wave transparent portion) are integrally molded.

### EXAMPLES

The present invention will be described below in more detail using Examples. The present invention is not intended to be limited by Examples.

In these Examples, product name: TR352E115S (thermosetting resin: epoxy resin #352 (produced by Mitsubishi Rayon Co., Ltd.), reinforcement fiber: carbon fiber (produced by Mitsubishi Rayon Co., Ltd., product name: TR50S)) produced by Mitsubishi Rayon Co., Ltd. was used as carbon fiber prepreg (unidirectional material) and product name: GE352E135S (thermosetting resin: epoxy resin #352 (produced by Mitsubishi Rayon Co., Ltd.), reinforcement fiber: glass fiber (produced by Unitika Ltd., product name: DR-235)) produced by Mitsubishi Rayon Co., Ltd. was used as glass fiber prepreg (unidirectional material).

As glass fiber prepreg (fabric material), fabric prepreg was used which was obtained by impregnating a thermosetting resin (epoxy resin #352 (produced by Mitsubishi Rayon Co., Ltd.)) into a glass fiber fabric (produced by Unitika Ltd., product name: KS 1020).

### Example 1

In order to obtain the molded fiber-reinforced composite material product illustrated in FIG. 3, a laminated body was prepared in which prepreg-joined sheets in the direction of 0° formed in such a manner that carbon fiber prepreg (unidirectional material) oriented in the direction of 0° and glass fiber prepreg (unidirectional material) oriented in the direction of 0° was joined to each other in an extending direction and prepreg-joined sheets oriented in the direction of 90° formed in such a manner that carbon fiber prepreg (unidirectional material) oriented in the direction of 90° and glass fiber prepreg (unidirectional material) oriented in the direction of 90° was joined to each other in an extending direction were laminated by six layers in this order of [90°/0°/0°/0°/0°/90°]. At this time, joining portions (joining lines) between the carbon fiber prepreg and the glass fiber prepreg are shifted by 10 mm from a joining center P as illustrated in FIG. 3. In addition, the glass fiber prepreg is arranged at one end. Thereafter, the prepreg was pressed for 60 minutes at a pressure of 3 MPa while being heated to 140° C. using the lower and upper molds, thereby integrally curing the laminated body of the prepreg. After the compression molding, the molded fiber-reinforced composite material product 11 having a thin sheet shape having a thickness of 0.60 mm was obtained by opening the metal mold.

### Example 2

The molded fiber-reinforced composite material product 21 having a thin sheet shape having the thickness of 0.60 mm was obtained in the same manner as in Example 1 except that positions of joining lines between carbon fiber prepreg and glass fiber prepreg were changed as illustrated in FIG. 4.

### Example 3

It is possible to obtain the molded fiber-reinforced composite material product 31 as illustrated in FIG. 5 in such a manner that from the configuration of Example 1, the material for the glass fiber prepreg of the outermost layer is changed into the fabric material from the unidirectional material and joining positions on layers other than the outermost layer are changed.

### Example 4

It is possible to obtain the molded fiber-reinforced composite material product 41 as illustrated in FIG. 6 in such a manner that the material for the glass fiber prepreg of the outermost layer in Example 2 is changed into the fabric material from the unidirectional material.

### Example 5

It is possible to obtain the molded fiber-reinforced composite material product 51 as illustrated in FIG. 7 in such a manner that the material for the glass fiber prepreg of the layers other than the outermost layer in Example 3 is changed into the fabric material from the unidirectional material.

### Example 6

It is possible to obtain the molded fiber-reinforced composite material product 61 as illustrated in FIG. 8 in such a manner that the material for the glass fiber prepreg of the layers other than the outermost layer in Example 4 is changed into the fabric material from the unidirectional material and the second layer and the third layer from the outside are interchanged with each other in the position of the joining line.

### Example 7

The molded fiber-reinforced composite material product 71 having a thin sheet shape having the thickness of 0.70 mm as illustrated in FIG. 9 was obtained in the same manner as in Example 1 except that the layer on which only the glass fiber prepreg (unidirectional material) having the glass fibers aligned in the 0° direction was formed was added to the center of symmetry of the laminated configuration in Example 1.

### Example 8

The glass fiber prepreg and the carbon fiber prepreg were joined with each other such that the fiber direction of the glass fiber prepreg (unidirectional material) on the outermost layer was a direction of 90° and the fiber direction of the carbon fiber prepreg (unidirectional material) on the outermost layer was a direction of 0°. In addition, the glass fiber prepreg and the carbon fiber prepreg were joined with each other such that the fiber direction of the glass fiber prepreg (unidirectional material) of the second layer from the outside was a direction of 0° and the fiber direction of the carbon fiber prepreg (unidirectional material) was a direction of 90°. Moreover, these kinds of prepreg were prepared such that positions of joining lines therebetween were arranged to be shifted by 10 mm as illustrated in FIG. 10. In addition, five inner layers were configured such that two layers formed with only glass fiber prepreg (unidirectional material) oriented in the direction of 0° and three layers formed with only glass fiber prepreg (unidirectional material) oriented in the direction of 90° were laminated in this order of [0°/90°/90°/90°/0°], and thus the laminated body was prepared as illustrated in FIG. 10. Thereafter, the molded fiber-reinforced composite material product 81 having a thin sheet shape having a thickness of 0.90 mm was obtained in the same molding manner as in Example 1.

All of the molded fiber-reinforced composite material products having configurations indicated in Examples described above could reduce thickness and weight while maintaining sufficient rigidity. In addition, all configurations of the molded fiber-reinforced composite material products are configured such that all of the layers in the thickness direction of the molded fiber-reinforced composite material product include the electromagnetic wave transparent portion formed only of the layer (glass fiber prepreg) for transmitting the electromagnetic wave. Accordingly, the electromagnetic wave can be excellently transmitted through all configurations of the molded fiber-reinforced composite material products.

### INDUSTRIAL APPLICABILITY

The molded composite material product according to the present invention can be suitably used as a case for electrical and electronic equipment such as a PC. In addition, the molded composite material product according to the present invention can be applied to aircraft parts, automobile parts, building materials, electrical household appliances, and medical instruments for which reduction in weight is required.

### EXPLANATIONS OF LETTERS OR NUMERALS

1, 11, 21, 31, 41, 51, 61, 71, and 81 . . . molded fiber-reinforced composite material products

2 . . . electromagnetic wave blocking portion

3 . . . electromagnetic wave transparent portion

4 . . . prepreg-joined sheet

5 . . . carbon fiber prepreg; unidirectional material of 90°

6 . . . carbon fiber prepreg; unidirectional material of 0°

7 . . . glass fiber prepreg; unidirectional material of 90°

8 . . . glass fiber prepreg; unidirectional material of 0°

17 . . . glass fiber prepreg; fabric material having warp direction of 90°

18 . . . glass fiber prepreg; fabric material having warp direction of 0°

20 . . . carbon fiber prepreg (electromagnetic wave blocking prepreg)

30 . . . glass fiber prepreg (electromagnetic wave transparent prepreg)

Q . . . joining line

1. A molded fiber-reinforced composite material product having a thin sheet shape, comprising:
an electromagnetic wave blocking prepreg comprising conductive fibers and a thermosetting matrix resin;
an electromagnetic wave transparent prepreg comprising non-conductive fibers and a thermosetting matrix resin;
a first layer formed by joining the electromagnetic wave blocking prepreg and the electromagnetic wave transparent prepreg together at a joining line perpendicular to a thickness direction of the molded fiber-reinforced composite material product;
a second layer formed on the first layer and including the electromagnetic wave transparent prepreg disposed to cover at least a portion of the joining line; and
an electromagnetic wave transparent section not including the electromagnetic wave blocking prepreg in the thickness direction.

2. The molded fiber-reinforced composite material product according to claim 1, wherein the second layer is formed by joining the electromagnetic wave blocking prepreg and the electromagnetic wave transparent prepreg together at a second joining line perpendicular to the thickness direction, and
in the state where the first layer and the second layer are laminated, such that both end portions of the first joining line and both end portions of the second joining line are disposed so as not overlap with each other on same lines.

3. The molded fiber-reinforced composite material product according to claim 1, further comprising a third layer which is formed on the opposite side of the second layer to the first layer and formed by joining the electromagnetic wave blocking prepreg and the electromagnetic wave transparent prepreg together at a joining line perpendicular to the thickness direction,
wherein the second layer is formed only from the electromagnetic wave transparent prepreg.

4. The molded fiber-reinforced composite material product according to claim 1, wherein the electromagnetic wave blocking prepreg and the electromagnetic wave transparent prepreg are unidirectional prepreg.

5. The molded fiber-reinforced composite material product according to claim 4, wherein the electromagnetic wave blocking prepreg and the electromagnetic wave transparent prepreg constituting the first layer are disposed such that fiber orientation directions thereof are perpendicular to each other.

6. The molded fiber-reinforced composite material product according to claim 5, wherein the second layer comprises unidirectional prepreg, and
the unidirectional prepreg of the first layer and the unidirectional prepreg of the second layer being adjacent to each other are laminated such that fiber orientation directions thereof are perpendicular to each other.

7. The molded fiber-reinforced composite material product according to claim 1, wherein the electromagnetic wave blocking prepreg is a unidirectional prepreg and the electromagnetic wave transparent prepreg is a fabric prepreg.

8. The molded fiber-reinforced composite material product according to claim 1, wherein the conductive fiber is a carbon fiber.

9. The molded fiber-reinforced composite material product according to claim 1, wherein the non-conductive fiber is a glass fiber.

10. The molded fiber-reinforced composite material product according to claim 1, wherein the thickness is 1.2 mm or less.

11. The molded fiber-reinforced composite material product according to claim 1, wherein the thickness is 0.6 mm or less.

12. A method of producing a molded fiber-reinforced composite material product, the method comprising:
preparing an electromagnetic wave blocking prepreg comprising conductive fibers and a thermosetting matrix resin and an electromagnetic wave transparent prepreg comprising non-conductive fibers and a thermosetting matrix resin;
forming a first layer by joining the electromagnetic wave blocking prepreg and the electromagnetic wave transparent prepreg together in directions perpendicular to the thickness direction;
forming a second layer, which include the electromagnetic wave transparent prepreg that covers at least a portion of the joining line between the electromagnetic wave shielding prepreg and the electromagnetic wave transmitting prepreg of the first layer, on the first layer, and thus forming a laminated body including the first layer and the second layer; and
curing the laminated body.
